(19) United States
(12) Patent Application Publication
(10) Pub. No.: US 2026/0333566 A1
(43) Pub. Date: Oct. 22, 2026

(54) MEMORY COOLING DEVICE WITH LATERAL VAPOR CHAMBERS

(71) Applicant: Micron Technology, Inc., Boise, ID (US)

(72) Inventors: Suresh Reddy Yarragunta, Bangalore (IN); Deepu Narasimiah Subhash, Bangalore (IN); Rakesh Chinhara, Hyderabad (IN); Ramesh Nallavelli, Hyderabad (IN)

(21) Appl. No.: 19/565,410

(22) Filed: Mar. 12, 2026

Related U.S. Application Data
(60) Provisional application No. 63/782,446, filed on Apr. 2, 2025.

(51) Int. Cl. H05K 1/02

(52) U.S. Cl. CPC H05K 1/0203; H05K 2201/10159

(57) ABSTRACT

A memory cooling device is disclosed, comprising a thermal energy storage device configured to manage the operating temperature of memory devices. The device includes a heat sink thermally coupled to the memory device and one or more laterally adjacent wickless vapor chambers containing a phase change material (PCM) to dissipate thermal energy from the memory device. The cooling device is designed to conform to compact form factors, such as an M.2 specification. The cooling device can include metal tabs for thermal and electrical coupling to a grounding layer of the memory device. The cooling device can include a notch configured above a mounting hole of the memory device, such that a fastening screw can mechanically and thermally couple the cooling device to the memory device and to a reference structure, such as a system motherboard.

### CROSS-REFERENCE TO RELATED APPLICATION(S)

The present application claims priority to U.S. Provisional Patent Application No. 63/782,446, filed Apr. 2, 2025, the disclosure of which is incorporated herein by reference in its entirety.

### BACKGROUND

Memory devices, such as persistent memory devices, have become increasingly important in modern computing systems due to their high performance and reliability. However, as these devices continue to increase in speed and capacity, they generate more heat during operation. Excessive heat can lead to reduced performance, data errors, and shortened lifespan of memory components. This has created a growing need for effective cooling solutions that can maintain optimal operating temperatures for memory devices.

Traditional cooling methods, such as fans and passive heat sinks, can struggle to keep up with the thermal demands of high-performance memory devices, especially in compact form factors like M.2 memory devices. These conventional approaches may not provide sufficient heat dissipation for extended periods of high-intensity operations, leading to thermal throttling and reduced performance. Additionally, many existing cooling solutions are not optimized for the unique thermal characteristics and space constraints of modern memory devices, limiting their effectiveness.

### BRIEF DESCRIPTION OF THE DRAWINGS

Detailed descriptions of implementations of the present invention will be described and explained through the use of the accompanying drawings.

FIG. 1 is a perspective view of an example apparatus in accordance with an implementation of the present technology.

FIG. 2 is a perspective view of a circuit module in accordance with an implementation of the present technology.

FIG. 3A is a first perspective view of a thermal energy storage device in accordance with an implementation of the present technology.

FIG. 3B is a second perspective view of a thermal energy storage device in accordance with an implementation of the present technology.

FIG. 4A is a cross-sectional view of the example apparatus along a dashed line 4A--4A of FIG. 1 in accordance with an implementation of the present technology.

FIG. 4B is a cross-sectional view of the example apparatus along a dashed line 4B--4B of FIG. 1 in accordance with an implementation of the present technology.

FIG. 5 is a flow diagram illustrating an example method of manufacturing an apparatus in accordance with an implementation of the present technology.

FIG. 6 is a schematic view of a system that includes an apparatus in accordance with an implementation of the present technology.

The technologies described herein will become more apparent to those skilled in the art from studying the Detailed Description in conjunction with the drawings. Embodiments or implementations describing aspects of the invention are illustrated by way of example, and the same references can indicate similar elements. While the drawings depict various implementations for the purpose of illustration, those skilled in the art will recognize that alternative implementations can be employed without departing from the principles of the present technologies. Accordingly, while specific implementations are shown in the drawings, the technology is amenable to various modifications.

### DETAILED DESCRIPTION

As described in greater detail below, the technology disclosed herein relates to an apparatus, such as for memory systems, systems with memory devices, related methods, etc., having a thermal energy storage device. The thermal energy storage device can be configured to control an operating temperature of a memory device, such as by removing thermal energy away from the memory device and dissipating the heat into the surrounding environment.

As an illustrative example, the memory device can be mounted on a substrate, such as for a memory module, and the thermal energy storage device can be attached over the substrate and the memory device. The thermal energy storage device can have a physical configuration that promotes heat dissipation while maintaining a limited height for the overall module. In some implementations, the thermal energy storage device can include one or more wickless vapor chambers connected to or integral with a heat sink. The heat sink can be configured thermally couple (e.g., through direct contact and/or thermally conductive material or adhesive) to a top surface of a memory device. The heat sink portion of the thermal energy storage device can be laterally attached to or integral with the one or more chambers containing a liquid or a phase change material. The phase change material can have a boiling temperature associated with a targeted operating temperature (e.g., an upper limit thereof) of the memory device. The thermal energy storage device can have multiple chambers each enclosing a space containing a phase change material, or can have a single chamber surrounding the heat sink.

During operation, the heat sink portion can absorb the thermal energy away from the memory device. The heat sink portion can transfer the absorbed thermal energy into the one or more chambers (e.g., wickless vapor chambers). Accordingly, the heat sink and the outer surfaces of the one or more chambers can increase the surface area for dissipating the absorbed thermal energy. The thermal energy storage device can further use the liquid or the phase change material within the one or more chambers to act as a heat sink/storage structure, thereby further increasing the amount or the capacity of energy absorbed from the memory device. In some implementations, the phase change material can include material having a phase change temperature (e.g., a melting temperature or a boiling temperature) at or within a threshold magnitude below an upper end (e.g., 60^{o} C, 70^{o} C, 85^{o} C, 100^{o} C, etc.) of an operating temperature range of the memory device. Some examples of the phase change material can include water, methanol, ethanol, other types of alcohol, or the like. As a result, the thermal energy storage device can increase the amount of thermal energy removed from the memory device, thus allowing the memory device to operate within the targeted operating temperature range for longer periods of time.

In some implementations, the thermal energy storage device is designed to be implemented on a memory apparatus conforming to an M.2 form factor. When mounted on a memory apparatus (e.g., a memory module), the bottom of the thermal energy storage device can be positioned above a printed circuit board (PCB) substrate of the memory apparatus with enough space to allow for other electronic components that are disposed onto the substrate. The thermal energy storage device can have metal tabs that extend from the bottom surface through the substrate and contact a layer inside the substrate, such as a ground layer, to electrically and thermally couple the device. The thermal energy storage device can have an attached notch configured to be positioned above a mounting hole on the memory apparatus, such that a fastener screw placed through both the notch and the mounting hole will structurally and thermally couple the thermal energy storage device to the memory apparatus. Thus, the thermal energy storage device can have a limited height, such as for satisfying the M.2 form factor, while providing the thermal management feature for the memory device.

In the following description, specific details are set forth to provide a thorough understanding of aspects of the present technology. One skilled in the relevant art will recognize, however, that the systems, devices, and techniques described herein can be practiced without one or more of the specific details set forth herein, or with other methods, components, materials, etc.

Reference throughout this specification to an “example” or an “embodiment” means that a particular feature, structure, or characteristic described in connection with the example or embodiment is included in at least one example or embodiment of the present technology. Thus, use of the phrases “for example,” “as an example,” or “an embodiment” herein are not necessarily all referring to the same example or embodiment and are not necessarily limited to the specific example or embodiment discussed. Furthermore, features, structures, or characteristics of the present technology described herein may be combined in any suitable manner to provide further examples or embodiments of the present technology.

Spatially relative terms (e.g., “beneath,” “below,” “over,” “under,” “above,” “upper,” “top,” “bottom,” “left,” “right,” “center,” “middle,” and the like) may be used herein for ease of description to describe one element’s or feature’s relationship relative to one or more other elements or features as illustrated in the figures. It will be understood that the spatially relative terms are intended to encompass different orientations of a device or system in use or operation, in addition to the orientation depicted in the figures. For example, if a device or system illustrated in the figures is rotated, turned, or flipped about a horizontal axis, elements or features described as “below” or “beneath” or “under” one or more other elements or features may then be oriented “above” the one or more other elements or features. Thus, the exemplary terms “below” and “under” are non-limiting and can encompass both an orientation of above and below. The device or system may additionally, or alternatively, be otherwise oriented (e.g., rotated ninety degrees about a vertical axis, or at other orientations) than illustrated in the figures, and the spatially relative descriptors used herein are interpreted accordingly. In addition, it will also be understood that when an element is referred to as being “between” two other elements, it can be the only element between the two other elements, or one or more intervening elements may also be present.

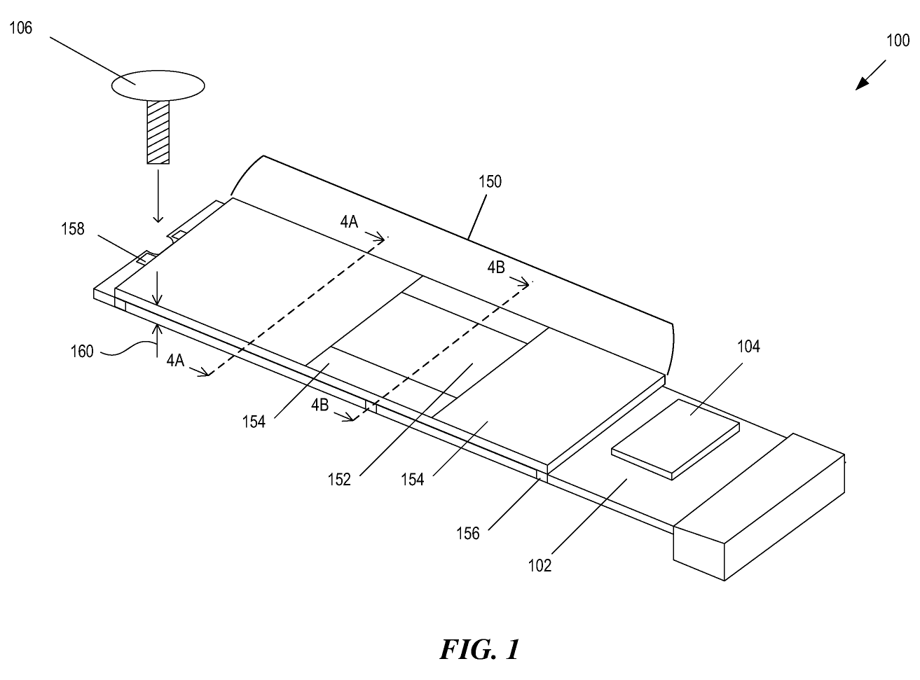

FIG. 1 is a perspective view of an example apparatus 100 (e.g., a memory apparatus) in accordance with an implementation of the present technology. The apparatus 100 can include a thermal energy storage device 150 (e.g., a vapor chamber cooling device) attached over a module, such as a memory module or card.

The module portion of the apparatus 100 can contain a substrate 102 (e.g., a printed circuit board (PCB)) having electronic components 104 attached thereon, including a memory device (e.g., a NAND storage chip/package). The substrate 102 can further include conductive elements (e.g., traces) that provide electrical connections between the electronic components 104 and/or one or more external devices (e.g., a system motherboard). The apparatus 100 can include a mounting receptacle that can be attached to an external structure (e.g., the system motherboard) using a screw 106.

The thermal energy storage device 150 (also referred to as the device 150) can be attached over the substrate 102. The apparatus 100 can be thermally coupled to the module, e.g. by coupling to a heat-generating component, such as a memory device (not shown in FIG. 1), that is mounted on the substrate 102. The device 150 can include a heat sink 152 configured to be placed directly over and thermally and/or mechanically coupled to the heat-generating component. The device 150 can have one or more sections 154 (four depicted in FIG. 1), which are thermally coupled to the heat sink 152 (via, e.g., direct attachments or integral connections). Each section can be fully enclosed, forming a chamber, and contain an enclosed material, such as a phase change material (PCM) or a different liquid. Alternately, multiple contiguous sections can form a single chamber and contain an enclosed material. A PCM contained in a chamber can be liquid at room temperature and vaporize at a critical/boiling temperature. For example, a PCM can be chosen such that the PCM vaporizes at the upper end of an operating temperature range of the memory device. Excess heat generated by the memory device will then be absorbed by the PCM, preventing the temperature of the memory device from increasing to unsafe temperatures. Furthermore, the device 150 can be configured to conform to a predetermined form factor. For example, the total height 160 of the apparatus 100 can conform to a predetermined height requirement, such as a height requirement of an M.2 form factor.

The device 150 can include a notch 158 configured to be disposed between the screw 106 and the mounting receptacle. As described in further detail below, the notch can structurally and thermally couple the device 150 to the substrate 102 and to one or more external devices. The memory apparatus 100 can also include tabs 156 extending the through the substrate 102 and contacting a layer (not shown in FIG. 1) in the substrate 102, such as a grounding layer.

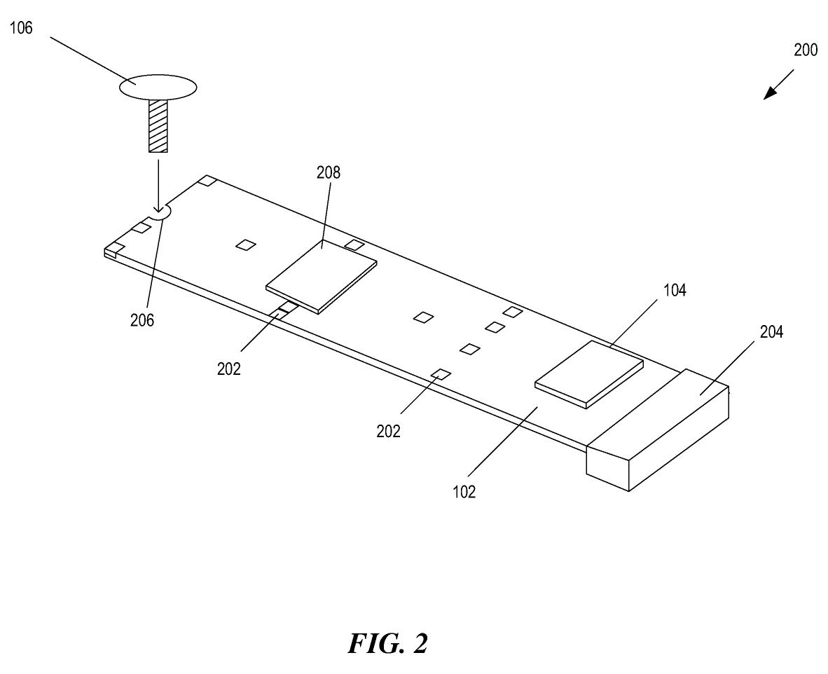

FIG. 2 is a perspective view of a circuit module 200 (e.g., a memory module) in accordance with an implementation of the present technology. FIG. 2 illustrates additional details regarding the module described above.

The circuit module 200 can include the substrate 102 (e.g., a PCB) that extends longitudinally and supports electronic components of the circuit module 200. The substrate 102 can further include conductive elements (e.g., traces) that provide electrical connections between the electronic components and/or one or more external devices (e.g., a system motherboard). The circuit module 200 can include one or more layers (not shown in FIG. 2) in the substrate 102, such as a grounding layer. The substrate 102 can include channels 202 extending from a top portion of the substrate to the one or more layers, which can be configured to receive metal tabs (e.g., the metal tabs 156 in FIG. 1). The circuit module 200 can include an interface 204 that structurally and communicably couples the circuit module 200 to one or more external devices, such as a motherboard through a corresponding connector. The circuit module 200 can also include a mounting receptacle 206 configured to receive the screw 106. The screw 106 secures the circuit module 200 to a mounting receptacle on an external reference structure (e.g., the one or more external devices coupled to the circuit module 200 by the interface 204). For example, the receptacle 206 can at least partially surround or abut against peripheral edges/surfaces of the thread portion such that the head portion of the screw 106 overlaps the substrate 102. Accordingly, when the screw 106 is driven into the external reference structure, the head portion of the screw 106 can press on (either directly or through an intermediate structure) the substrate 102 about the receptacle 206, thereby physically attaching and/or securing the circuit module 200 relative to the external reference structure.

The circuit module 200 includes one or more memory devices 208 (e.g., a NAND storage chip/package) mounted on the substrate 102. The circuit module 200 can include other electronic components 104, such as a controller, a power module, and the like. During operation, components of the module, such as the memory device 208, will heat up as they are used. Such components have a range of operating temperatures within which the components will provide expected results. If the temperature of a component increases beyond the upper range of its operating temperatures, the component can malfunction or fail (e.g., erroneous reads, inaccurate writes, etc.).

Some circuit modules will include components intended to remove or distribute thermal energy away from hot components. One example is a heat sink, a passive cooling component disposed directly onto a hot component and composed of a thermally conductive material, which conducts heat from the component and radiates the heat into the surrounding environment. More efficient cooling components include large heat sinks with shapes designed for more efficient transfer of heat, or active cooling components such as fans or liquid cooling devices.

However, cooling components require additional space, making them impractical for use in compact devices. For example, the circuit module 200 can be designed to conform to a predetermined form factor, such as an M.2 form factor, which places restrictions on the dimensions of the module. In particular, an M.2 form factor places a height restriction on the device, precluding the attachment of conventional cooling structures directly onto the components of the circuit module 200, such as the memory device 208.

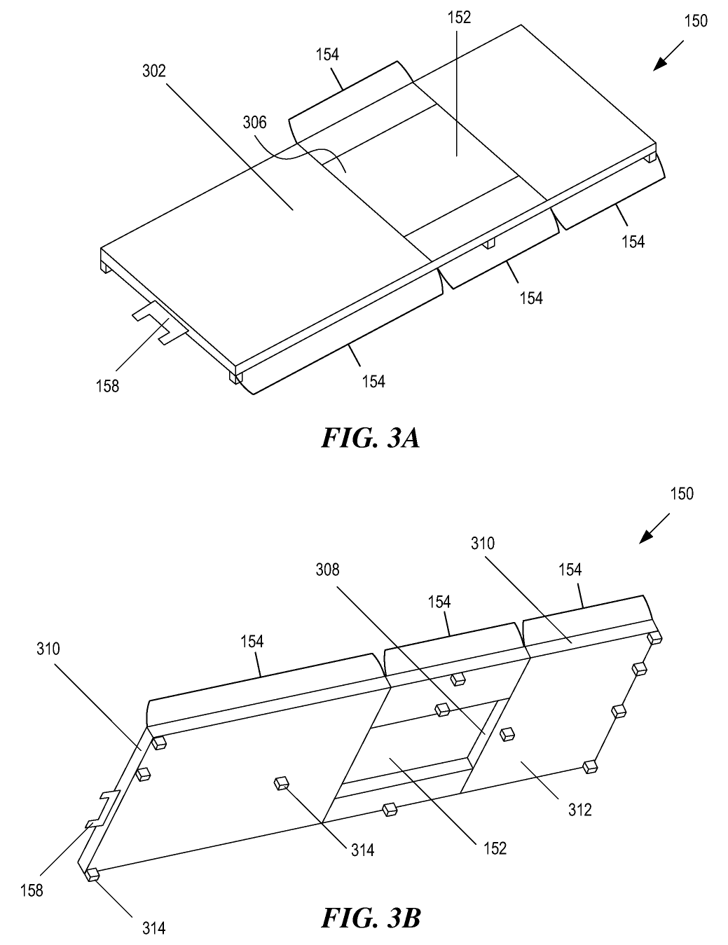

FIGS. 3A and 3B illustrate perspective views of a thermal energy storage device (e.g., the device 150 of FIG. 1) in accordance with an implementation of the present technology. FIGS. 3A and 3B illustrate additional details regarding the thermal energy storage device described in FIG. 1. The thermal energy storage device can be configured to remove thermal energy away from one or more components on the circuit module 200 (FIG. 2), such as the memory 208 (FIG. 2). In some embodiments, the thermal energy storage device can be configured to accommodate other components (e.g., passive components) while fitting into a targeted form factor, such as M.2. As described below, the thermal energy storage device can include one or more features configured to increase the capacity to remove the thermal energy from the targeted device while conforming to a targeted form factor.

FIG. 3A is a first perspective view of a thermal energy storage device 300 in accordance with an implementation of the present technology. FIG. 3A illustrates additional details of the device 150 that can be configured for use with a memory apparatus, such as the apparatus 100 in FIG. 1 and/or the circuit module 200 in FIG. 2. The device 150 includes the heat sink 152 and the one or more sections 154 (four shown in FIG. 3A) arranged laterally adjacent to the heat sink 152. The heat sink 152 can be configured to cover and/or thermally couple to a top portion of a memory device, such as the memory device 208 shown in FIG. 2. The heat sink 152 can be coupled to the memory device by direct contact and/or by a thermally conductive/interfacing material or adhesive. The heat sink 152 can be composed of a thermally conductive material to efficiently transfer thermal energy away from the memory device. In some implementations, the heat sink 152 includes copper or titanium.

The device 150 can have one ore more of the sections 154 attached to or integral with the heat sink 152. Depending on various factors, such as the location of the heat-generating device relative to the peripheral edges of the substrate 102, the device 150 can include the section arranged along a length (e.g., between the interface 204 and the mounting receptacle 206) and/or a width of the substrate 102 and/or the device 150. Each section 154 can include a top cover 302 that is thermally coupled (e.g., through direct contact) to the heat sink 152 and can have a top surface coplanar with a top surface 306 of the heat sink.

In some implementations, the device 150 contains a notch 158 that is connected to or integral with one of the sections 154, such as the section that defines a peripheral edge nearest to the mounting receptacle 206 of FIG. 2. The notch 158 can be configured to align with a mounting receptacle on a memory apparatus, such as the mounting receptacle 206 of circuit module 200. This allows the notch 158 to be disposed between the mounting receptacle 206 and a fastener screw, such as the screw 106 in FIGS. 1 and 2 . The fastener screw structurally and/or thermally couples the thermal energy storage device to the memory apparatus. The fastener screw may further be inserted into a mounting receptacle located on an external reference structure (e.g., a system motherboard), structurally and thermally coupling the device 300 and the memory apparatus to the external structure. For example, protrusions of the notch 158 can extend adjacent to the thread portion of the screw 106 can be overlapped by the head portion of the screw 106. Accordingly, when the screw 106 is engaged or tightened, the head portion of the screw 106 can press on (e.g., via direct contact) the notch 158 and the mounting receptacle 206. Thus, the notch 158 can engage the screw 106 and secure/affix the device 150 relative the module 200.

FIG. 3B illustrates a different perspective view of the device 150. The device 150 includes the heat sink 152 and the one or more sections 154 (four shown in FIG. 3B) arranged laterally adjacent to the heat sink 152. Each section includes at least one inner sidewall 308 connected to or integral with the top cover 302 of FIG. 3A, extending below the top cover 302. The inner sidewall 308 can be configured to be adjacent to and/or directly contact a peripheral portion of the heat-generating device that is coupled to the heat sink 152. The device 150 can further include (1) at least one outer sidewall 310 connected to or integral with the top cover 302 and extending below the top cover 302 and (2) a bottom cover 312 connected to or integral with the inner sidewall(s) 308 and the outer sidewall(s) 310. The inner and outer sidewalls can establish or define each of the sections 154. These components can be made of a thermally conductive material in order to facilitate heat transport and dissipation. In some implementations, the heat sink 152, the top cover 302, the at least one inner sidewall 308, the outer sidewalls 310, the bottom cover 312, or a combination thereof includes copper or titanium. The one or more sections 154 can each enclose a separate space, forming individual chambers that contain a liquid or a phase change material. In other implementations, the one or more sections 154 do not each enclose a separate space, but together enclose a contiguous space, forming a single chamber. In some implementations, the four sections 154 in FIG. 3B form a single ring-shaped chamber surrounding and laterally adjacent to a memory device coupled to the heat sink 152, enclosing a space that contains a liquid or a phase change material. That is, the at least one inner sidewall 308 includes at least four inner sidewalls that are connected to or integral with one another, such that the inner sidewalls 308 encircle the heat-generating device (such as a memory device) that is coupled to the heat sink 152, forming a chamber that encloses a ring-shaped space that laterally surrounds the heat-generating device. Additionally, the device 150 may include a liquid (e.g., water) or a phase change material within the enclosed space. The liquid can act as a storage material for the removed heat. The phase change material can be configured to change phases (e.g., evaporate) within a threshold range from an upper operating temperature limit of the heat-generating device.

The device 150 can include one or more metal tabs 314 extending from the bottom cover of one or more sections 154. The tabs 314 can be configured to extend through a top portion of the substrate of a memory apparatus (e.g., through indentations or channels in the substrate), such as the substrate 102 of memory apparatus 200 in FIG. 2. The tabs 314 can be configured to contact and/or thermally couple to a layer in the substrate, which can be a grounding layer. This can allow the device 150 to electrically couple to a grounding layer in the substrate and provide electromagnetic shielding to the components that may be disposed onto the substrate. Furthermore, the tabs 314 can be configured to provide space between the top of the substrate and the bottom cover(s) 312 of the sections 154 of the device 350. In other words, the tabs 314 can have a height/length that is greater than the depth of the indentations or channels in the substrate. Accordingly, the bottom covers 312 can be vertically offset or above a top surface of the substrate 102. This allows the device 150 to be positioned above the substrate of the memory apparatus with enough space to allow for other electronic components (e.g., passive components) that are mounted on the substrate. In some implementations, the device 150 provides 2 mm of clearance space between the substrate and the bottom cover 312.

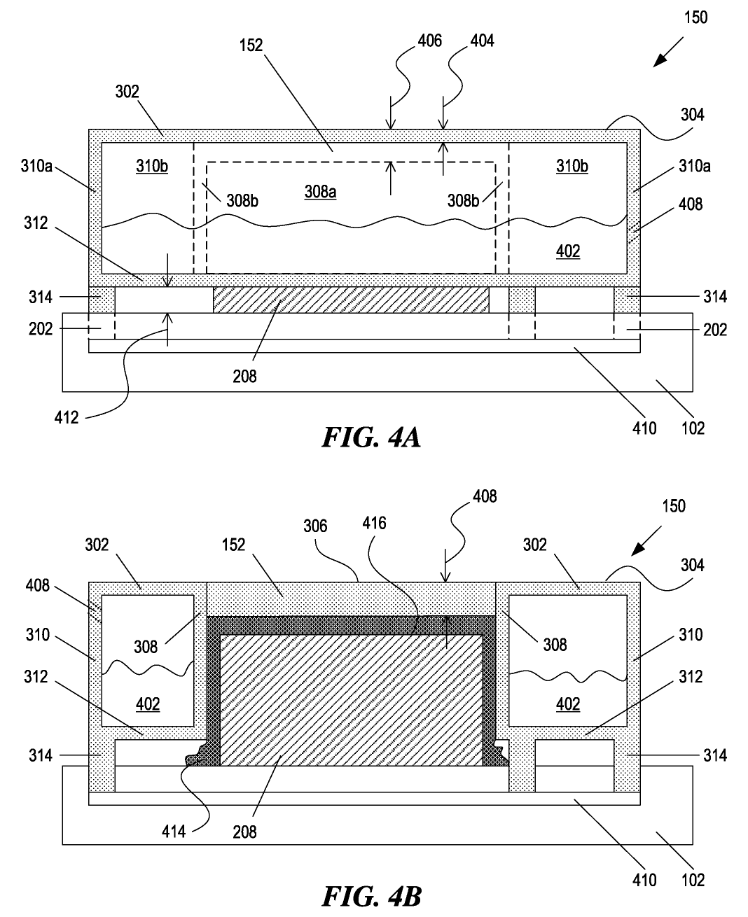

FIGS. 4A and 4B illustrate cross-sectional views of the device 150 in accordance with an implementation of the present technology. FIGS. 4A and 4B illustrate additional details regarding the thermal energy storage device described in FIGS. 1 and 3 .

FIG. 4A is a cross-sectional view of an apparatus along a dashed line 4A--4A of FIG. 1 in accordance with an implementation of the present technology. The dashed lines in FIG. 4A indicate structures of the thermal energy storage device that correspond with structures shown in FIG. 4B and which, in some implementations, may not be visible in the cross-sectional view of FIG. 4A.

In an implementation, a section is formed by the top cover 302, the at least one inner sidewall 308a (analogous to inner sidewall 308 in FIG. 3B) adjacent to a peripheral portion of the memory device 208, the outer sidewalls 310a, 310b (analogous to outer sidewalls 310 in FIG. 3B), and the bottom cover 312. The section fully encloses a space, forming a chamber. The enclosed space contains an enclosed material 402 that is in liquid form at room temperature. The material 402 can be a PCM that is liquid at room temperature and vaporizes at a critical/boiling temperature. In other embodiments, the material 402 can include water.

In another implementation, the outer sidewalls 310b are not present, and the heat sink 152 and inner sidewalls 308b can be seen in the cross-section, as indicated by the dashed lines in FIG. 4A. A section is formed by the top cover 302, the at least one inner sidewall 308a adjacent to a peripheral portion of the memory device 208, the outer sidewalls 310a, and the bottom cover 312. The section is not fully enclosed, and instead, the multiple sections 154 (e.g., the four shown in FIG. 3B) form a single ring-shaped chamber laterally surrounding the memory device 208. This chamber is formed by one or more top covers (including the top cover 302), at least four inner sidewalls (including the inner sidewalls 308a and 308b) that laterally encircle the memory device 208, the outer sidewalls 310a, and the bottom cover 312. The outer sidewalls 310a are thus connected and/or integral with each other and are connected to the inner sidewalls 308a, 308b via the top cover 302 and the bottom cover 312. The chamber fully encloses a ring-shaped space that contains the enclosed material 402. Whether in separate/sectional chambers or continuous chamber/space, the device 150 can include a wickless vapor chamber.

In some implementations, the thickness 404 of the top cover 302 is different than the thickness 406 of the heat sink 152. For example, the thickness 406 of the heat sink 152 can be greater than the thickness 404 of the top cover 302. In some implementations, one or more sections can include filling ports 408 (e.g., in the top cover 302, the inner sidewalls 308a, 308b, the outer sidewalls 310a, and/or the bottom cover 312). The filling port can be used to inject the enclosed material 402 into the one or more chambers during manufacturing. The filling ports 408 can be closed (e.g., by welding, blocking, or plugging) after the enclosed material 402 has been injected.

In some implementations, the thermal energy storage device includes one or more metal tabs 314 extending from the bottom cover 312 through the substrate 102 (e.g., through channels 202) and contacting and/or thermally coupling to a layer 410 (such as a ground layer) in the substrate 102. In some implementations, the device 150 can be configured such that the bottom cover 312 is at least a target height 412 above the surface of the substrate 102, which can allow clearance for other electronic components that are disposed onto the substrate 102. For example, the bottom cover 312 can be at least 2 mm above the surface of the substrate 102.

FIG. 4B is a cross-sectional view of the example apparatus (e.g., the device 150) along a dashed line 4B--4B of FIG. 1 in accordance with an implementation of the present technology. The device 150 can contain multiple sections (two shown in FIG. 4B, to the left and right of the memory device 208), each including the top cover 302, one or more inner sidewalls 308, outer sidewalls 310, and a bottom cover 312. In some implementations, each section is separated from other sections and encloses a space, forming a chamber containing the material 402. In some implementations, sections are not separated, and the sections together enclose a space, forming a single chamber containing the material 402. In some implementations, the top cover 302 is thermally coupled to the heat sink and has a top surface 304 that is coplanar with the top surface 306 of the heat sink.

In some implementations, the device 150 uses a thermal interface material 414. The interface material 414 can facilitate the exchange of heat and/or attach the heat sink 152 to the heat-generating device (e.g., the memory device 208). The interface material can be disposed between the heat sink 152 and the top portion 416 of the memory device 208, and/or between the one or more inner sidewalls 308 and the memory device 208. In some implementations, the interface material 414 is a thermal interface material, and is disposed between the top portion 416 of the memory device 208 and one or both of the heat sink 152 and the one or more inner sidewalls 308, such that the interface material thermally couples the memory device to the heat sink and/or a chamber of the thermal energy storage device.

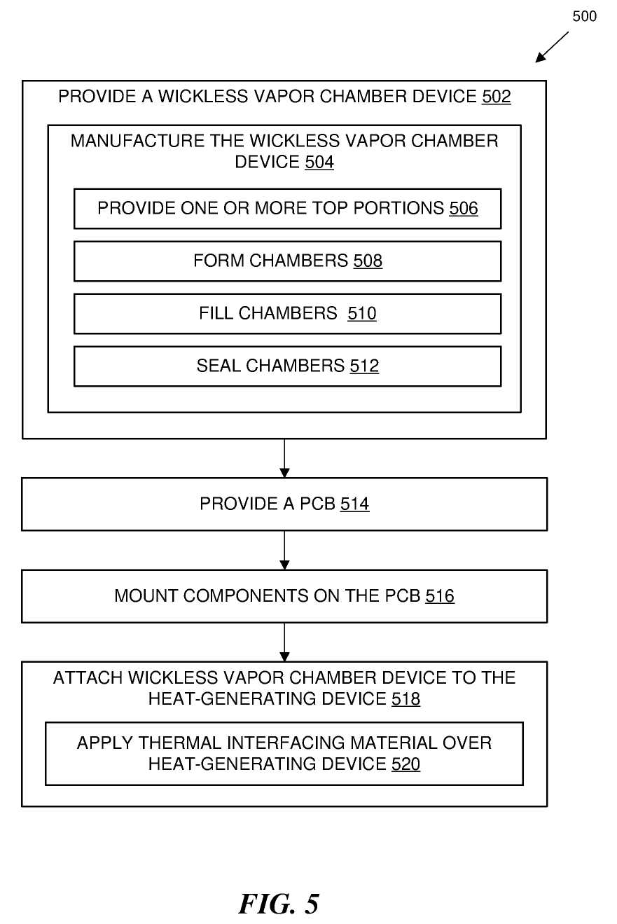

FIG. 5 is a flow diagram illustrating an example method 500 of manufacturing an apparatus in accordance with an implementation of the present technology. The method 500 can be for manufacturing one or more of the apparatuses described above (e.g., the apparatus 100 of FIG. 1, the thermal energy storage device 150 of FIG. 1, and/or the circuit module 200 of FIG. 2). For example, the method 500 can be for manufacturing a device, such as a NAND flash memory device conforming to an M.2 form factor, having a thermal energy storage device (e.g., wickless vapor chamber cooling device).

At block 502, the method 500 can include providing a wickless vapor chamber device (e.g., the thermal energy storage device 150). For example, the method 500 can include obtaining the wickless vapor chamber device having a heat sink and one or more chambers at locations that correspond to the final apparatus. Alternatively, the wickless vapor chamber device can be provided by manufacturing the wickless vapor chamber, as illustrated at block 504.

As an illustrative example of manufacturing the wickless vapor chamber device, at block 506, the method 500 can include providing one or more top portions for the wickless vapor chamber. The one or more top portions can include a heat sink (e.g., the heat sink 152 of FIG. 1) configured to directly contact or interface with (via, e.g., a thermal interface material) with a heat generating device. The one or more top portions can also include one or more top covers (e.g., the top cover 302 of FIG. 3A) for one or more sections, the one or more top covers being connected to or integral with the heat sink such that a top surface of the top covers is coplanar with a top surface of the heat sink.

At block 508, the method 500 can include forming one or more sections for the wickless vapor chamber device. For example, the method 500 can include providing the one or more inner sidewalls 308 of FIG. 3B, the one or more outer sidewalls 310 of FIG. 3B, and one or more bottom covers 312 of FIG. 3B, which are attached (e.g., via welding) together with the top cover 302 of FIG. 3A to form one or more chambers. In another example, the one or more inner sidewalls 308, the one or more outer sidewalls 310, and/or the one or more bottom covers 312 can be integral with the top cover 302 (e.g., being milled as a single piece and positioned via bending), and are attached (e.g., via welding) with one another and/or any additional components (e.g., inner sidewalls 308, outer sidewalls 310, and/or bottom covers 312) that are not integral with the top cover 302. Any of the components forming the one or more chambers can include one or more filling ports (e.g., the filling port 408 of FIG. 4A). The components included in the one or more chambers, namely the top covers, inner walls, outer walls, and bottom covers, can completely enclose one or more spaces, with the exception of any filling ports. Block 508 can also include forming or attaching other structures onto the wickless vapor chamber device, such as one or more metal tabs 314 of FIG. 3 and/or the notch 158 of FIGS. 1 and 3.

At block 510, the method 500 can include filling the one or more chambers with a material that is a liquid (e.g., water) at room temperature. Also, the material can be a PCM that can be liquid at room temperature and vaporize at a critical temperature. The one or more chambers can be filled by injecting the material into any filling ports present in the one or more chambers.

At block 512, the method 500 can include sealing the chambers. This can include blocking the filling ports with a material and/or welding the filling ports. The chambers can each be fully enclosed and contain an enclosed material.

At block 514, the method 500 can include providing a PCB. Providing the PCB can include preparing the PCB for surface mount. For example, the PCB may include channels configured to receive one or more metal tabs protruding from the bottom of the wickless vapor chamber device and allow a connection between the one or more metal tabs and a grounding layer in the PCB.

At block 516, the method 500 can include mounting components on the PCB. For example, a memory package, such as a NAND storage chip, can be mounted on the PCB. One or more of the mounted components, such as the memory package, can include a heat-generating component.

At block 518, the method 500 can include attaching the wickless vapor chamber device (e.g., the device 150) to the heat-generating device. This can include attaching the heat sink portion of the device 150 directly to the heat-generating device (e.g., the memory device 208) or connecting the heat sink through the use of an interface material (e.g., the interface material 414 of FIG. 4B). Attaching the wickless vapor chamber device can also include inserting or aligning one or more metal tabs according to corresponding channels (e.g., channels 202 of FIG. 2) in the PCB.

Attaching the wickless vapor chamber device to the heat-generating device can include the application of an interface material. For example, at block 520, the method 500 can include applying a thermal interfacing material (e.g., the interface material 414) over the heat-generating device. The wickless vapor chamber device can then attach to the heat-generating device such that the heat sink and/or the one or more inner sidewalls are directly touching the thermal interfacing material. Furthermore, the wickless vapor chamber device can be attached such that the one or more top portions and/or the heat sink are a certain maximum height from a top surface of the PCB. For example, this can allow the completed device to conform to height requirements, such as a height requirement of an M.2 form factor.

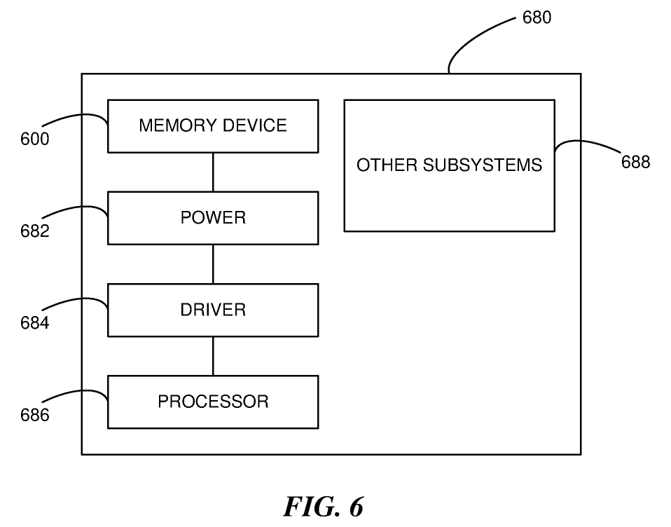

FIG. 6 is a schematic view of a system that includes an apparatus in accordance with embodiments of the present technology. Any one of the foregoing apparatuses (e.g., memory devices) described above with reference to FIGS. 1-5 can be incorporated into or implemented in memory (e.g., a memory device 600) or any of a myriad of larger and/or more complex systems, a representative example of which is system 680 shown schematically in FIG. 6. The system 680 can include the memory device 600, a power source 682, a driver 684, a processor 686, and/or other subsystems or components 688. The memory device 600 can include features generally similar to those of the apparatus described above with reference to FIGS. 1-5 and can therefore include various features for performing a direct read request from a host device. The resulting system 680 can perform any of a wide variety of functions, such as memory storage, data processing, and/or other suitable functions. Accordingly, representative systems 680 can include, without limitation, hand-held devices (e.g., mobile phones, tablets, digital readers, and digital audio players), computers, vehicles, appliances and other products. Components of the system 680 may be housed in a single unit or distributed over multiple, interconnected units (e.g., through a communications network). The components of the system 680 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the Figures described above.

We claim:

1. An apparatus comprising:
a printed circuit board (PCB);
a memory device mounted on the PCB;
a heat sink configured to cover and thermally couple to a top portion of the memory device; and
at least one chamber laterally adjacent to and thermally coupled to the heat sink, the at least one chamber including:
a top cover thermally coupled to the heat sink and having a top surface coplanar with a top surface of the heat sink,
at least one inner sidewall connected to or integral with the top cover and extending below the top cover, the at least one inner sidewall configured to be adjacent to or directly contact a peripheral portion of the memory device,
outer sidewalls connected to or integral with the top cover and extending below the top cover, wherein the at least one inner sidewall and the outer sidewalls encircle a space, and
a bottom cover connected to or integral with the at least one inner sidewall and the outer sidewalls, wherein the top cover, bottom cover, at least one inner sidewall, and outer sidewalls enclose the space, and
an enclosed material within the enclosed space, wherein the enclosed material is in liquid form at room temperature.

2. The apparatus of claim 1, wherein the heat sink, the top cover, the at least one inner sidewall, the outer walls, the bottom cover, or a combination thereof includes copper or titanium.

3. The apparatus of claim 1, further comprising:
a thermal interface material disposed between the heat sink and the top portion of the memory device, the at least one inner sidewall, or a combination thereof, wherein the thermal interface material thermally couples the memory device to the heat sink, the at least one chamber, or a combination thereof.

4. The apparatus of claim 1, wherein the memory device comprises at least one NAND flash memory device.

5. The apparatus of claim 1, wherein the heat sink has a greater thickness than the top cover of the at least one chamber.

6. The apparatus of claim 1, further comprising:
one or more metal tabs extending from the bottom cover and configured to contact and thermally couple to a layer within the PCB.

7. The apparatus of claim 1, wherein the top surface of the top cover is at a height above the substrate conforming to an M.2 form factor.

8. The apparatus of claim 1, wherein the bottom cover is at least 2 mm above the surface of the PCB.

9. The apparatus of claim 1, further comprising a notch attached the at least one chamber.

10. The apparatus of claim 9, wherein the notch includes parallel extensions that laterally extend away from the at least one chamber and configured to be disposed between the PCB and a screw that physically affixes the PCB to a reference structure.

11. The apparatus of claim 1, wherein:
the at least one chamber includes a first chamber and a second chamber defined by the top cover, the at least one inner sidewall, the outer sidewalls, and the bottom cover, wherein (1) the first chamber encloses the space and the PCM and (2) the second chamber encloses a second space and a second PCM.

12. The apparatus of claim 1, wherein:
the at least one inner sidewall includes at least four inner sidewalls that are connected to or integral with one another, such that the inner sidewalls encircle the memory device; and
the at least one chamber enclosing the space that laterally surrounds the memory device.

13. A thermal energy storage device comprising:
a heat sink configured to cover and thermally couple to a top portion of a memory device and remove thermal energy from the memory device; and
at least one chamber laterally adjacent to and thermally coupled to the heat sink, the at least one chamber comprising:
a top cover thermally coupled to the heat sink and having a top surface coplanar with a top surface of the heat sink,
at least one inner sidewall connected to or integral with the top cover and extending below the top cover, the inner sidewall configured to be adjacent to or directly contacting a peripheral portion of the memory device,
outer sidewalls connected to or integral with the top cover and extending below the top cover, wherein the inner sidewall and the outer sidewalls are connected to or integral with each other and encircle a space,
a bottom cover connected to or integral with the inner and the outer sidewalls, wherein, the top cover, the bottom cover, the inner sidewalls, and the outer sidewalls enclose the space, and
a phase change material (PCM) within the enclosed space for increasing storage and dissipation of the thermal energy removed from the memory device.

14. The thermal energy storage device of claim 13, further comprising:
one or more metal tabs extending from the bottom cover and configured to electrically and thermally couple a layer of a printed circuit board disposed under the memory device.

15. The thermal energy storage device of claim 14, wherein the overall height of the thermal energy storage device is no greater than 1.5 mm.

16. The thermal energy storage device of claim 13, further comprising a notch in the at least one chamber.

17. The thermal energy storage device of claim 13, wherein the heat sink, the top cover, the at least one inner sidewall, the outer walls, the bottom cover, or a combination thereof includes copper or titanium.

18. The thermal energy storage device of claim 13, wherein the heat sink has a different thickness than the thickness of the top cover of the at least one chamber.

19. The thermal energy storage device of claim 13, wherein:
the at least one chamber comprises a first chamber and a second chamber defined by the top cover, the at least one inner sidewall, the outer sidewalls, and the bottom cover, wherein (1) the first chamber encloses the space and the PCM and (2) the second chamber encloses a second space and a second PCM.

20. A method of manufacturing a memory device, comprising:
providing a printed circuit board;
mounting a memory package on the printed circuit board; and
attaching a wickless vapor chamber device on the memory package, wherein the attached wickless vapor chamber device includes:
a heat sink portion attached to a top surface of the memory package,
at least one chamber laterally adjacent to the memory package and connected to or integral with the heat sink portion, the at least one chamber having (1) a top portion coplanar with the top surface, (2) a set of sidewalls extending down from the top portion, and (3) a bottom cover attached to or integral with the set of sidewalls, the top portion, the set of sidewalls, and the bottom cover enclosing a space;
liquid within the enclosed space of the at least one chamber,
wherein the wickless vapor chamber device is configured to draw thermal energy away from the memory package through the heat sink portion, store the thermal energy within the one or more chambers, including the liquid therein, and dissipate the stored thermal energy,
wherein the wickless vapor chamber device is attached such that the top portion and the heat sink portion are within a maximum height from a top surface of the printed circuit board.
